(19) United States
(12) Patent Application Publication
(10) Pub. No.: US 2003/0006749 A1
(43) Pub. Date: Jan. 9, 2003

(54) Current sensing and measurement in a pulse width modulated power amplifier

(75) Inventor: Charles Rollman, Sudbury, MA (US)

Correspondence Address: WEINGARTEN, SCHURGIN, GAGNEBIN & LEBOVICI LLP, TEN POST OFFICE SQUARE, BOSTON, MA, 02109, US

(73) Assignee: Copley Controls Corporation

(21) Appl. No.: 10/162,376

(22) Filed: Jun. 4, 2002

Related U.S. Application Data
(60) Provisional application No. 60/302,873, filed on Jul. 3, 2001.

(51) Int. Cl. G01R 19/00

(52) U.S. Cl. 324/76.11

(57) ABSTRACT

A current sensor apparatus is disclosed for use with an inverter bridge that is controlled by a pulse width modulator (PWM) control apparatus and is connected to an inductive load. The current sensor apparatus includes a plurality of current sensors disposed in series with each of the low side switches in the inverter bridge. The PWM control apparatus samples the current sensors when the PWM control apparatus provides the necessary signals to open all of the high side switches in the inverter bridge and to close all of the low side switches. Due to the inductive nature of the load, the load current will continue to flow during the time in which the low side switches are closed and the high side switches are open. During this time, the current sensors are sampled and provide an output signal that is indicative of the magnitude of the current. The PWM control apparatus limits the duty cycle of the PWM signals to a predetermined value that is less than 100%. The actual value of the duty cycle limit is determined to ensure that the pulse width of the PWM signals is sufficiently wide to allow for accurate and reliable current sampling. If the load comprises motor windings that are connected in a “wye” configuration, the current sensors need only be inserted into all but one of the low side switch circuits. In this instance, the current that is not sensed may be derived from the measurements of the other currents.

### CROSS REFERENCE TO RELATED APPLICATIONS

This application claims priority under 35 U.S.C. §119(e) to U.S. Provisional Patent Application Serial No. 60/302,873, filed Jul. 3, 2001.

### STATEMENT REGARDING FEDERALLY SPONSORED RESEARCH OR DEVELOPMENT

N/A

### BACKGROUND OF THE INVENTION

Applications that use electric motors typically require the motor torque, position, and/or velocity to be maintained at certain values. Motor torque is generally proportional to the motor winding current. This allows allows the control of the desired motor output parameters through the accurate control of the motor winding current. Typically, servo amplifiers are used to accurately control the motor winding current. Servo amplifiers can include one or more current-feedback loops. These current-feedback loops measure the motor current(s) and compare the measured value(s) against one or more desired motor current values. The servo amplifier adjusts the voltage applied to the motor to minimize the difference between the desired motor current and the measured motor current. Accordingly, accurate measurement of the motor current is required to provide the necessary accuracy of the motor currents.

Typically, the accurate measurement of motor winding current uses a variation of one of two methods: a resistive shunt or a Hall current sensor. Hall sensors tend to be expensive, physically large, and offer limited resolution. They are therefore not the preferred solution for many applications.

A resistive shunt produces a voltage in response to the measured current. The resistive shunt has a known resistance value, the voltage that is produced by the measured current flowing therethrough is measured, and the current is determined according to Ohm's law. However, because dissipation in a resistor is a function of the square of the current while voltage is proportional to current, resistive shunts do not provide an advantageous tradeoff between sensitivity and power dissipation, particularly, at higher current levels. For this reason a low value shunt resistor is used so as to limit dissipation but provides differential voltages that are small, although manageable, in terms of the voltage magnitude.

A problem with the use of resistive shunts is the placement of the resistive shunt in the electrical supply network for the motor. Ideally, the resistive shunt would be placed in series with the corresponding motor lead, since it is the current in this lead which is to be measured and controlled. However this would require small resistance to avoid introducing substantial voltage drops in the motor circuits and corresponding large power dissipation in the sensor. Thus, the small resistances used in a shunt type current sensor in series with the motor winding will typically produce a differential voltage that is on the order of several tens of millivolts. Conventional motors may have switched or time varying motor winding voltages that are a hundred volts or more. Amplifying and measuring a several millivolt signal in the presence of a large ac common mode voltage of a hundred volts or more is technically challenging. One solution to this problem is the use of isolation amplifiers that use opto-coupler technology. In this case, opto-isolators are modulated with the differential voltage across the sense resistor and transmit the modulated signal across the isolation barrier for subsequent demodulation and measurement. However, opto-isolators require an isolated power supply, a signal conditioning differential amplifier, an analog-to-digital converter (“ADC”) or modulator, and a demodulator. The complexity of these circuits can adversely affect the cost and size of the servo amplifier which incorporates them. Another method of current measurement in a motor system that uses a bridge inverter voltage switching system is to place resistive shunts on the low side switches in the inverter. However, as pointed out in the paper “Eliminate Ripple Current Error from Motor Current Measurement” by Eric Persson and Toshio Takahashi from International Rectifier, which is available on the International Rectifier website, this technique has problems as well. In particular, as the paper points out, the motor current is sensed only when the low side switches are closed and the high side switches are open. This condition occurs in a PWM system at the zero vector state that corresponds to a negative peak of the PWM triangle wave. However, in PWM systems the voltage applied to the motor is proportional to the duty cycle. Accordingly, it is advantageous to allow for a high duty cycle to maintain as high a voltage applied to the motor as possible. A PWM system will therefore reduce the width of the pulses closing the low side switches concomitantly with the increase of the duty cycle. In the limit in which the duty cycle approaches 100%, the pulses become shorter and shorter and ultimately disappear entirely making the sampling of current extremely difficult.

Therefore, what is needed is an inexpensive, accurate, and technically simple approach to measuring currents in PWM motor control systems.

### BRIEF SUMMARY OF THE INVENTION

A current sensor apparatus is disclosed for use with an inverter bridge that is controlled by a pulse width modulator (PWM) control apparatus and is connected to an inductive load. The current sensor apparatus includes a plurality of current sensors disposed in series with each of the low side switches in the inverter bridge. The PWM control apparatus samples the current sensors when the PWM control apparatus provides the necessary signals to open all of the high side switches in the inverter bridge and to close all of the low side switches. Due to the inductive nature of the load, the load current will continue to flow during the time in which the low side switches are closed and the high side switches are open. During this time, the current sensors are sampled and provide an output signal that is indicative of the magnitude of the current. The PWM control apparatus limits the duty cycle of the PWM signals to a predetermined value that is less than 100%. The actual value of the duty cycle limit is determined to ensure that the pulse width of the PWM signals is sufficiently wide to allow for accurate and reliable current sampling. If the load comprises motor windings which are connected in a “wye” configuration, the current sensors need only be inserted into all but one of the low side switch circuits. In this instance, the current that is not sensed may be derived from the measurements of the other currents.

In one embodiment, a current measurement apparatus is disclosed that includes a bridge inverter including a voltage source having first and second terminals. The bridge inverter also includes a high side switch having an input terminal and a switched output terminal and a low side switch having an input terminal and a switched output terminal. Both the high side switch and the low side switch operate in either an open state in which no current flows, or a closed state in which current flows from the input terminal to the switched output terminal. The input terminal of the high side switch is coupled to the first terminal of the voltage source. The output terminal of the high side switch is electrically coupled to the input terminal of the low side switch, and the output to the motor winding is taken at this junction. The current sensing apparatus further includes a current sensor connected in series between the switched output of the low side switch and the second terminal of the voltage source.

A controller provides a high side control signal and a low side control signal to the high side and low side switches respectively. The high side and low side control signals control the state of the respective switches and, in addition, the high side and low side control signals are out of phase with one another. The controller is operative to provide a sample time period during which the current is sensed. During the sample time period, the controller is operative to provide an open state for the high side switch and to provide a closed state for the low side switch for at least a portion of the sample time period. The controller is operative to limit the duty cycle of the high side switch to ensure that the duty cycle is less than 100% and provides a sample time period that allows for accurate sampling.

Other forms, features and aspects of the above-described methods and system are described in the detailed description that follows.

### BRIEF DESCRIPTION OF THE SEVERAL VIEWS OF THE DRAWING

The invention will be more fully understood by reference to the following Detailed Description of the Invention in conjunction with the Drawing of which:

FIG. 1 is a block diagram of one embodiment of the current sensing apparatus described herein;

FIG. 2 is a diagram of waveforms corresponding to the operation of the embodiment depicted in FIG. 1; and

FIG. 3 is a schematic diagram of a current sensor suitable for use with the current sensing apparatus depicted in FIG. 1.

### DETAILED DESCRIPTION OF THE INVENTION

The disclosure of U.S. Provisional Patent Application Serial No. 60/302,873, filed Jul. 3, 2001 is incorporated herein by reference.

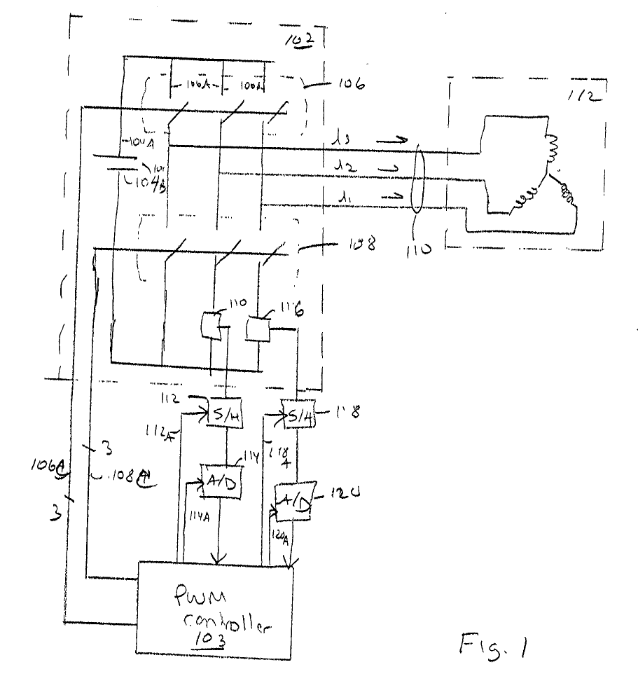

A current sensing system is illustrated in FIG. 1 that provides for sensing the current in one or more motor windings. FIG. 1 depicts a current sensing system that includes an inverter bridge 102 that contains a voltage source 104, a plurality high side switches 106, and a plurality of low side switches 108. Each of the high side switches 106 includes an input terminal 106A that is connected to a first terminal 104A of the voltage source 104. Each of the high side switches 106 also includes an output switch terminal 106B. Each of the low side switches 108 includes an input terminal 108A that is connected to the switched output terminal 106B of a corresponding high side switch 106. Each of the low side switches 108 also includes an output switch terminal 108B. The motor current is provided to one or more motor windings 112 via a plurality of output current lines 110. Each of the plurality of output current lines 110 is coupled to a corresponding output of the inverter bridge 102 that is the interconnection between the switched output terminal 106B of the respective high side switch 106, and the input terminal 108A of the respective low side switch 108. Each of the high side and low side switches can be in one of two states: an open state in which no current flows through the switch and a closed state in which current flows through the switch.

In the illustrative embodiment of FIG. 1, the three high side switches 106 and the three low side switches 108 receive commands from a controller 103 via 3 high side control lines 106C and 3 low side control lines 108C respectively. Each of the high side switches 106 and low side switches 108 is controlled by a signal on a single control line that controls the state of the respective switch. The controller 103 provides the high side and low side control signals 106C and 108C. In the illustrated embodiment controller 103 is a pulse width modulated (PWM) controller.

The PWM controller 103 adjusts duty cycle of the square wave output voltage that is applied to each motor winding by providing appropriate on/off control signals to the high side and low side switches 106 and 108 respectively. It is important to note that the on/off control signals provided to the corresponding high side and low side switches are out of phase with one another. This is to prevent the occurrence of an electrical short circuit if both the high side and low side switches were closed simultaneously. The duty cycle of the control signals provided to the high side and low side switches 106 and 108 determines the the voltage, and therefore the resulting currents i₁, i₂, and i₃ that are provided to the motor windings 112. It is important that the duty cycle of the high side switch 106 be limited as high as possible without equaling 100%. Similarly, it is important that the duty cycle of the low side switch be limited as low as possible without equaling 0%. As will be explained in more detail below, the duty cycle of the high side switch and low side switch are selected to ensure that a sampling period is sufficiently long to ensure accurate current sampling. In the illustrated embodiment, the motor windings 112 are connected in a “wye” configuration. Motor windings, such as those in motor windings 112, are highly inductive in nature. As such, the motor current flowing through the respective winding continues to flow if the respective supply current i₁, i₂, or i₃ is interrupted for a short period. It is this continued flow of current that the current sensor described herein relies upon for proper operation.

A first current sensor 110 is disposed in series between the switched output terminal 108A of the respective low side switch and the second terminal 104B of the voltage source 104. A second current sensor 118 is disposed in series between the switched output terminal 108A of the respective low side switch and the second terminal 104B of the voltage source 104. Each current sensor provides an output signal that is indicative of the magnitude of the current flowing through the respective current sensor. As will be explained below, due to the configuration of the motor windings 112, in the illustrative embodiment, no current sensor is needed in the third circuit.

Taking advantage of the inductive nature of the motor windings discussed above, the PWM controller 103 is operative to provide a sampling time period to sense and sample the current to be measured. During the sampling time period, the plurality of high side switches are in the open state and the plurality of low side switches are in the closed state for a predetermined period of time. The predetermined period of time is selected to allow for the accurate sampling of the measured current. During this sampling time period, the current that was flowing in each of the respective motor currents i₁, i₂, and i₃ continues to flow through the low side switch and through the respective series connected current sensor. The motor current i₁ is sensed by current sensor 116 and the motor current i2 is sensed by current sensor 110. Because the motor windings are connected in a wye configuration the balanced currents in each arm of the wye sum to zero. Accordingly, the current i₃ is the negative of the sum of the currents i₁ and i₂ and may be determined without having to physically sense the current magnitude.

Sample and hold modules 112 and 118 are coupled to the current sensor 110 and 116 respectively. In the illustrative embodiment, the sample and hold modules 112 and 118 receive current sample control signals 112A and 118A respectively from the PWM controller. The sample and hold modules 112 and 118 are responsive to the current sample control signals 112A and 118A by providing a sampled output of the respective current sensor to analog to digital converters 114 and 120 respectively. The analog and digital converters 114 and 120 receive (simultaneous) current convert control signals 114A and 120A, respectively, from the PWM controller 103. The analog to digital converters 114 and 120 are responsive to the respective current convert control signals 114A and 120A by providing a digitized representation of the sampled output signal to the PWM controller 103.

The embodiment depicted in FIG. 1 is for illustrative purposes only, and the current sensing system described herein is not limited to the illustrated embodiments. In particular, although the embodiment depicted in FIG. 1 uses three (3) high side and three (3) low side switches, the current sensing techniques for inductive loads described herein may be used in PWM systems utilizing one (1), two (2), or more than three (3) switches. As discussed above, the motor windings are in a wye configuration and accordingly only two (2) of the three (3) low side switches include current sensors, where as discussed above the third current is calculated from the two currents that are measured. Other load configurations may be used in which the net sum of the output currents is not equal to a constant as in the case of a wye configuration. If these other load configurations are used an additional current sensor can be placed in series with the remaining low side switch to provide direct indicia of the magnitude of the current flowing therein.

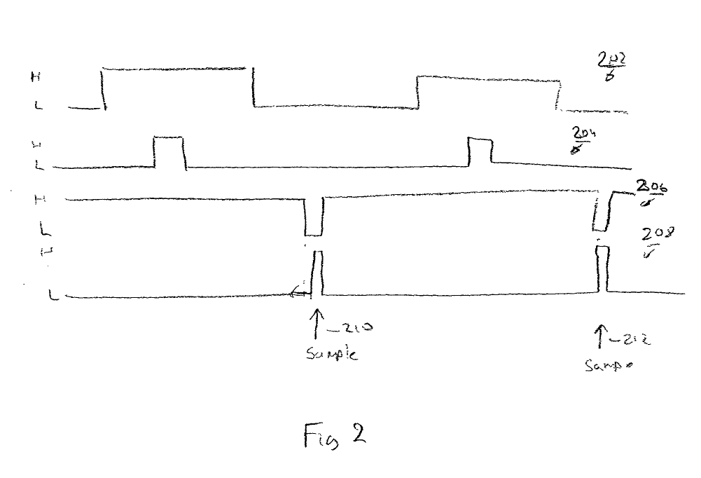

FIG. 2 depicts a timing diagram that is illustrative of the necessary timing of the various signals used in the embodiment depicted in FIG. 1. Waveforms 202, 204, and 206 illustrate a typical three-phase center-aligned PWM waveform. As illustrated, a “high” signal is indicative of the respective high side switch being in a closed state and the respective low side switch in the open state. As discussed above, this out of phase condition is necessary to avoid electrically short-circuiting the power supply directly to ground in the event that both switches were closed and conducting. In the illustrative embodiment, at the center of each PWM cycle all of the high side switches are opened and all of the low side switches are closed forming a single sample period. This sample period is selected to sample the currents at the midpoint of the current ramp for that cycle. Sampling at the midpoint of the current ramp in a PWM cycle ensures that the current that is sampled is the average current value for that PWM period. During this sample period, a current sample signal 208 is provided to the sample and hold module and, if desired, a current convert signal (not shown) is provided to the analog to digital converter. In the embodiment depicted in FIG. 2, there are two (2) PWM periods illustrated and a first and second sampling pulses 210 and 212 are provided.

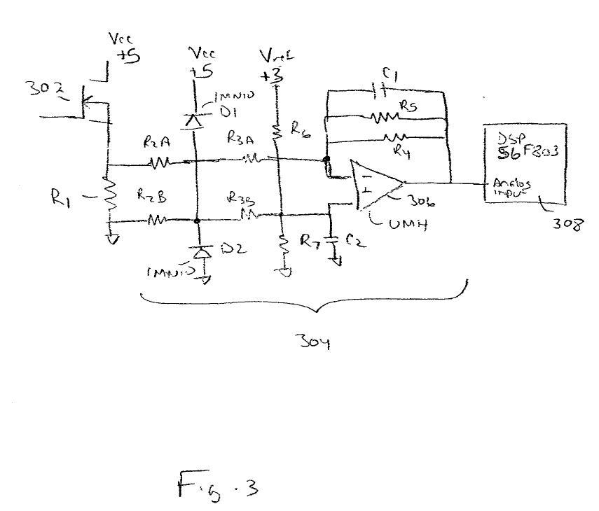

A variety of current sensors may be employed as the current sensors 110 and 116 depicted in FIG. 1. In a preferred embodiment depicted in FIG. 3, the low side switch is a MOSFET power transistor switch 302 that is selected based on the system requirements such as the maximum current and switching time. The MOSFET power transistor switch 302 receives control signals via a gate driver (not shown) and switches between an open state and a closed state in response to the received control signals. A current sensing resistor R1 is disposed in series with the source of the low side MOSFET power transistor switch 302 and ground. A differential amplifier with gain 304 is formed by an operational amplifier 306 and the associated resistors and capacitors. The differential amplifier 304 provides an output signal to the analog input of a DSP chip 308. As discussed above, this output is a series of pulses due to the timing of the sample time periods. A sample and hold circuit (not shown) and a/d converter are contained within the DSP 308 and are controlled thereby.

The differential amplifier 304 includes two input resistors R2a and R2b coupled to the source side and low side of the current sensing resistor R1 respectively. The two input resistors R2a and R2b are coupled series resistors R3a and R3b respectively, and the series resistors are coupled to the negative and positive input of the op-amp 306 respectively. To avoid unsettling the differential amplifier 304 due to any cross-conduction spikes that may be present on the switching stage and therefore appearing across the current sensing resistor R1, the junction of resistors R2b and R3b is clamped to Vcc, which is +5 volts in the preferred embodiment, and ground by diodes D1 and D2. The feedback resistors R4 and R5 are selected to provide the required gain of the differential amplifier 304, which is given by (R5||R4)/(R2a+R3a). In the preferred embodiment, R4=R5=2k, R2a=140, R3a=140, and the gain is 3.57. Resistors R6 and R7 are connected to the positive input of the op-amp 306 to balance the structure of the differential amplifier 304. R6 is connected between Vref, +3 volts, and the positive input of the op-amp 306 and R7 is connected between the positive input of the op-amp 306 and ground. This combination provides an impedance that is equal to the feedback resistance of R5 and R4 to provide for equal gain of the two inputs to the op-amp 306. In the illustrated embodiment the reference voltage, Vref is three (3) volts. Thus, the voltage division of resistors R6 and R7 adds an offset of Vref/2, or 1.5 volts, at the output of op-amp 306 to center the output signal within the input voltage range of the DSP 308 as discussed above. The bandwidth of the differential amplifier 304 is limited by capacitors C1 and C2. This serves to reduce the noise sensitivity of the differential amplifier. The time constants of the two filters are C1(R5||R4) and c4(R6||R7) respectively and are both equal to approximately 100 ns. This time constant ensures that the differential amplifier 304 will settle to twelve bit accuracy within about one (1) microsecond.

It should be noted that the differential amplifier used in the illustrative embodiment can be replaced by other types of amplifiers. In particular, the differential amplifier in the illustrative embodiment is particularly useful when the amplifier is placed in an electrically remote location. If the amplifier is remote to the sensor resistor ground currents between the ground connection of the sensor resistor and the grounded input terminal of the amplifier cause a voltage drop that reduces the accuracy of the amplified voltage across the sensor resistor. A differential amplifier will remove this voltage drop and will not be affected by the ground currents. Accordingly, if the amplifier is placed proximate to the sensor resistor, any amplifier having suitable parameters may be used.

As discussed above, the duty cycle of the high side sample switches should be as high as possible but less than 100%. Similarly, the duty cycle of the low side switches should be as low as possible but greater than 0%. These limits on the duty cycle of the respective switches ensures that the sampling period exists and is sufficiently long to allow the sampling and conversion of the measured voltage. Accordingly, the sample-and-hold (S/H) and analog-to-digital converter (ADC) should be sufficiently fast to allow the sample and hold circuit and the analog to digital converter to sample and convert the sensor voltages in a timely manner and to allow a duty cycle as high as possible. In the illustrative embodiment, dual S/H and ADC circuits are contained within the DSP chip. However, external S/H and ADC circuits could be used if the speed of the respective circuits was sufficiently high. In the illustrative embodiment, the dual S/H and ADC has 12-bit resolution, and single conversion time for two inputs of 1.25 μs.

In a preferred embodiment depicted in FIG. 3, the differential amplifier 306 is a wide bandwidth amplifier having a bandwidth of approximately 150 MHz to provide for accurate tracking of the voltage waveform. A suitable op-amp is the LMH6643MM available from National Semiconductor Santa Clara, Calif. In addition, the sample and hold module and the digital to analog converter module can be incorporated into a single controller that is also used as the PWM controller. As discussed above, in the preferred embodiment depicted in FIG. 3 a Motorola DSP56F803 is used as the DSP 308. The Motorola DSP56F803 is preferred due to the motion specific functionality contained therein. Other DSP chips, op-amps, Vcc voltages, and Vref voltages, may be selected depending on the overall system requirements.

In another embodiment, the sample and hold module includes a gain term so that the differential amplifier 306 is not needed.

Those of ordinary skill in the art should further appreciate that variations to and modification of the above-described methods, apparatus and system for current sensing and measurement in a PWM amplifier may be made without departing from the inventive concepts disclosed herein. Accordingly, the invention should be viewed as limited solely by the scope and spirit of the appended claims.

What is claimed is:

1. A current measurement apparatus comprising:
a bridge inverter including;
a voltage source having first and second terminals;
a high side switch having an input terminal and a switched output terminal, the high side switch having an open state when no current flows and a closed state when current flows from the input terminal to the switched output terminal;
a low side switch having an input terminal and a switched output terminal, the low side switch having an open state when no current flows and a closed state when current flows from the input terminal to the switched output terminal;
the input terminal of the low side switch electrically coupled to the switched output terminal of the high side switch;
the input terminal of the high side switch electrically coupled to the first terminal of the voltage source,;
a controller providing a high side control signal, wherein the high side control signal controls the state of the high side switch, the controller further providing a low side control signal, wherein the low side control signal controls the state of the low side switch, the controller being operative to set the high side and low side switches out of phase with one another and to set a duty cycle associated with the high side switch to be less than 100%;
a current sensor connected in series between the switched output of the low side switch and the second terminal of the voltage source the current sensor operative to provide a current sensor output signal;
a sample and hold module coupled to the current sensor output signal, the sample and hold module operative to sample the current output signal during a sample time period.

2. The current measurement apparatus in claim 1 wherein the current sensor includes:
a current sensing resistor, disposed in series in-between the switched output terminal of the low side switch and the second terminal of the voltage source;
a differential amplifier having first and second input terminals, the first and second terminals electrically connected across the current sensing resistor and an output;
wherein the differential amplifier provides an output signal that is indicative of the current flowing through the current sensing resistor.

3. The current sensing apparatus of claim 2 wherein the differential amplifier includes:
an op-amp having inverting and non-inverting inputs and an output;
a first input resistor coupled to the connection between the current sensing resistor and the switched output terminal of the low side switch;
a second input resistor coupled to the connection between the current sensing resistor and the second terminal of the voltage source;
a first feedback resistor coupled between the op-amp output and the op-amp inverting input;
a second feedback resistor coupled between the op-amp non-inverting input and the second terminal of the voltage source.

4. The current sensing apparatus of claim 3 wherein the first input resistor and the second input resistor have substantially equivalent resistance values and wherein the first feedback resistor and the second feedback resistor have substantially equivalent resistance values.

5. The current sensing apparatus of claim 3 further including a first capacitor coupled between the op-amp output and the inverting input of the op-amp forming a first filter in combination with the first feedback resistor, the first filter having a first time constant; and
a second capacitor coupled between the non-inverting input of the op-amp and the second terminal of the voltage source forming a second filter in combination with the second feedback resistor, the second filter having a second time constant.

6. The current sensing apparatus of claim 5 wherein the first and second capacitor have substantially equivalent capacitance values.

7. The current sensing apparatus of claim 6 wherein the first and second time constants are substantially equivalent.

8. The current sensing apparatus of claim 1 wherein the controller is a pulse width modulated (PWM) controller.

9. The current sensing apparatus of claim 8 wherein the PWM controller is operative to periodically provide the high side switch is at an open state and substantially simultaneously provide that the low side switch is at a closed state for a predetermined minimum time period, the controller further operative to sample each of the plurality of current sensors.

10. The current sensing apparatus of claim 8 wherein the PWM controller is operative to provide a center aligned PWM signal such that at the approximate middle of each PWM cycle the controller is operative to provide the high side switch at an open state and substantially simultaneously provide the low side switch at a closed state for a predetermined minimum time period.

11. The current sensing apparatus of claim 1 further including:
an analog to digital converter coupled to the sample output of the sample and hold module, the analog to digital converter operative to provide a digital representation of the sampled output.

12. The current sensing apparatus of claim 1 wherein the high side switch includes a plurality of high side switches and the low side switch includes a plurality of low side switches, and the current sensor includes a plurality of current sensors, each connected to a corresponding low side switch, wherein the controller provides a plurality of high side control signals and a plurality of low side control signals, and wherein during the sampling time period each of the plurality of high side switches is in the open state and each of the plurality of low side switches is in the closed state.

13. A method for sensing currents in a bridge inverter including a high side switch having an input terminal and a switched output terminal, the high side switch having an open state when no current flows and a closed state when current flows from the input terminal to the switched output terminal, a low side switch having an input terminal and a switched output terminal, the high side switch having an open state when no current flows and a closed state when current flows from the input terminal to the switched output terminal, the input terminal of the low side switch electrically coupled to the switched output terminal of the high side switch, the input terminal of the high side switch electrically coupled to the first terminal of the voltage source, the method comprising the steps of:
providing a high side control signal to the high side switch to set the high side switch to the open state;
providing substantially simultaneously to the high side switch set open, a low side control signal to the low side switch to set the low side switch to the closed state wherein the duty cycle associated with the high side switch is less than 100% and the duty cycle associated with the low side switch is greater than 0%;
sampling the output signal of a current sensor connected in series between the switched output terminal of the low side switch and the second terminal of the voltage source.
